(19) United States
(12) Patent Application Publication
(10) Pub. No.: US 2025/0264529 A1
(43) Pub. Date: Aug. 21, 2025

(54) LOGIC DIE, SEMICONDUCTOR DEVICE INCLUDING THE SAME, AND METHOD OF FEEDBACK TESTING OF THE SAME

(71) Applicant: Samsung Electronics Co., Ltd., Suwon-si (KR)

(72) Inventors: Geonho KIM, Suwon-si (KR); Kyeongkeun KANG, Suwon-si (KR); Shinyoung YI, Suwon-si (KR); Kwanyeob CHAE, Suwon-si (KR)

(73) Assignee: Samsung Electronics Co., Ltd., Suwon-si (KR)

(21) Appl. No.: 18/935,130

(22) Filed: Nov. 1, 2024

(30) Foreign Application Priority Data
Feb. 21, 2024 (KR) 10-2024-0025309
Apr. 18, 2024 (KR) 10-2024-0052398

(51) Int. Cl. G01R 31/3181; G01R 31/28; G01R 31/317

(52) U.S. Cl. CPC G01R 31/31813; G01R 31/2812; G01R 31/31713

(57) ABSTRACT

Provided are a logic die performing a feedback test operation, a semiconductor device including a logic die, and a feedback test operation on the logic die. The logic die includes a test circuit configured to generate test data for a feedback test operation, through silicon vias configured to communicate with a memory die, and an interface circuit connected between the test circuit and the through silicon vias. The interface circuit includes a TSV input/output circuit connected to one through silicon via, a write path, and a read path. In a first test mode for the logic die, the test data is fed back to the test circuit via the write path and the read path, and in a second test mode for the logic die, the test data is fed back to the test circuit via the write path, the TSV input/output circuit, the through silicon via, and the read path.

### CROSS-REFERENCE TO RELATED APPLICATIONS

This application is based on and claims ranking under 35 U.S.C. § 119 to Korean Patent Applications No. 10-2024-0025309, filed on Feb. 21, 2024 and 10-2024-0052398, filed on Apr. 18, 2024 in the Korean Intellectual Property office, the disclosures of which are incorporated by reference herein in their entirety.

### BACKGROUND

The inventive concepts relate to a semiconductor device, and more particularly, to a logic die, a semiconductor device including the logic die, and a method of feedback testing of the logic die.

As an example of semiconductor devices, dynamic random access memory (DRAM) is a volatile memory which determines data by the charge stored in a capacitor. As an example of the DRAM, a high bandwidth memory (HBM) providing an input/output in a multi-channel interface method is employed in various systems, such as graphics, servers, supercomputers, and networks, which require high performance and low power. The HBM may include a base die and core dies stacked in a vertical direction on the base die, and the base die may be connected to the core dies via a plurality of through silicon vias (TSVs). As the semiconductor process becomes refined, the possibility of a short circuit occurring between the plurality of TSVs may increase.

### SUMMARY

The inventive concepts provide a logic die on which a feedback test may be performed, a semiconductor device including the logic die, and a method of feedback testing of the logic die.

According to an aspect of the inventive concepts, there is provided a logic die including a test circuit configured to generate test data for a feedback test operation on the logic die, a plurality of through silicon vias (TSVs) configured to communicate with a memory die, and an interface circuit connected between the test circuit and the plurality of TSVs, the interface circuit including a write path, a read path, and a TSV input/output circuit connected to a TSV from the plurality of TSVs, wherein the logic die is configured such that, in a first test mode of the logic die, the test data is fed back to the test circuit via the write path and the read path and not via the TSV input/output circuit, and wherein the logic die is configured such that, in a second test mode of the logic die, the test data is fed back to the test circuit via the write path, the TSV input/output circuit, the TSV, and the read path.

In addition, according to another aspect of the inventive concepts, there is provided a semiconductor device including a logic die including a memory controller, a test circuit, an interface circuit, and a plurality of through silicon vias (TSVs), and a plurality of memory dies stacked on the logic die, and electrically connected to the logic die via the plurality of TSVs, respectively, wherein the interface comprises a write path, a read path, and a TSV input/output circuit connected to a TSV from the plurality of TSVs, wherein the logic die is configured such that, in a first test mode of the logic die, test data is fed back to the test circuit via the write path and the read path and not via the TSV input/output circuit, and wherein the logic die is configured such that, in a second test mode of the logic die, the test data is fed back to the test circuit via the write path, the TSV input/output circuit, the TSV, and the read path.

Furthermore, according to another aspect of the inventive concepts, there is provided a method of feedback testing of a logic die comprising a test circuit, an interface circuit, and a plurality of through silicon vias (TSVs) configured to communicate with a memory die, wherein the interface circuit comprises a TSV input/output circuit connected to one among the plurality of TSVs, a write path, and a read path, the method comprising: transmitting test data from the test circuit to the write path; generating, in first test mode of the logic die, first test mode feedback data by giving feedback of the test data to the test circuit via the write path and the read path; testing, in the first test mode, the write path and the read path by comparing the first test mode feedback data to the test data; generating, in a second test mode of the logic die, second test mode feedback data by giving feedback of the test data to the test circuit via the write path, the TSV input/output circuit, the TSV, and the read path; and testing, in the second test mode, the TSV input/output circuit and the TSV by comparing the second test mode feedback data to the test data.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to at least one embodiment;

FIGS. 2A and 2B schematically illustrate structures of semiconductor devices, according to some embodiments;

FIGS. 3A and 3B illustrate logic dies according to some embodiments;

FIG. 4A illustrates a high bandwidth memory (HBM) system according to at least one embodiment, and FIG. 4B illustrates an HBM system according to at least one embodiment;

FIG. 5 is a detailed block diagram of a logic die according to at least one embodiment;

FIG. 6 is a block diagram of an interface circuit according to at least one embodiment;

FIG. 7 shows a table representing a transmission enable signal and a receiving enable signal per operation mode, according to at least one embodiment;

FIG. 8A shows an operation of an interface circuit in an internal feedback test mode according to at least one embodiment, and FIG. 8B shows an operation of an interface circuit in an external feedback test mode according to at least one embodiment;

FIG. 9 is a flowchart of a method of feedback testing of a logic die, according to at least one embodiment;

FIG. 10 is a flowchart of a method of feedback testing of a logic die, according to at least one embodiment;

FIG. 11 illustrates a logic die including a through silicon via (TSV) array according to at least one embodiment;

FIG. 12 illustrates an example of a feedback test operation of a logic die, according to at least one embodiment;

FIG. 13 illustrates an example of a feedback test operation of a logic die, according to at least one embodiment;

FIG. 14 illustrates a feedback test operation of a logic die, according to at least one embodiment;

FIG. 15 illustrates an HBM semiconductor device according to at least one embodiment;

FIGS. 16A and 16B illustrate HBM semiconductor devices according to some embodiments; and

FIGS. 17A and 17B illustrate electronic systems including semiconductor devices according to some embodiments.

### DETAILED DESCRIPTION OF THE EMBODIMENTS

Hereinafter, embodiments of the inventive concepts are described in detail with reference to the accompanying drawings. Identical reference numerals are used for the same constituent elements in the drawings, and duplicate descriptions thereof are omitted. Further, functional elements, like those described with terms like “units”, “circuit”, -er/-or”, and/or which denote functional elements that process at least one function or operation, may be realized by processing circuitry such as, hardware, software, or a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc.

Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

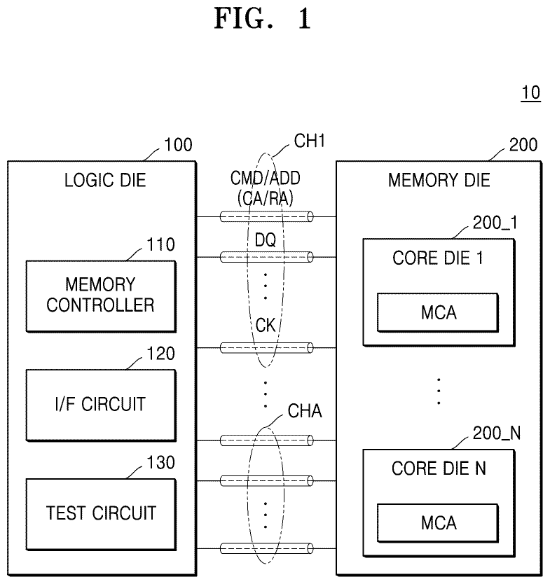

FIG. 1 is a block diagram of a semiconductor device 10 according to at least one embodiment.

Referring to FIG. 1, the semiconductor device 10 may include a logic die 100 and a memory die 200. According to some embodiments, the semiconductor device 10 may be referred to as a memory device, a memory system, a storage device, a storage system, and/or the like. According to some embodiments, the logic die 100 may be referred to as a logic chip, a base die, a controller, a controller chip, a controller die, a host, and/or the like. According to some embodiments, the memory die 200 may be referred to as a memory chip or a core die. For example, the memory die 200 may include a plurality of memory dies or a plurality of core dies 210_1 through 210_N each including a memory cell array MCA (N is a natural number of 2 or more). The number of core dies included in the memory die 200 may be variously changed according to some embodiments.

The logic die 100 may include a memory controller 110 and an interface (I/F) circuit 120. The memory controller 110 may be configured to control an overall operation of the memory die 200 including a write operation and a read operation of the memory die 200. The I/F circuit 120 may be configured to perform interfacing between the memory controller 110 and the memory die 200. According to some embodiments, the I/F circuit 120 may be referred to as a memory interface or a memory interface circuit.

The logic die 100 may transmit a command/address CMD/ADDR and a clock signal CK to the memory die 200 via the I/F circuit 120. For example, the command/address CMD/ADDR may include a column address CA and a row address RA (e.g., a column/row address CA/RA). In addition, the logic die 100 may transmit data DQ (e.g., write data) to the memory die 200 via the I/F circuit 120, and/or receive the data DQ (e.g. read data) from the memory die 200.

In at least one embodiment, the logic die 100 may further include a test circuit 130, and the test circuit 130 may be configured to control a feedback test operation for the logic die 100. For example, the test circuit 130 may provide test data for a feedback test operation to the I/F circuit 120. In this case, the “feedback test operation” may be defined as an operation of detecting defects in the connection terminals of the I/F circuit 120 and/or the logic die 100 in advance, by feeding the test data provided by the test circuit 130 back to the test circuit 130 via the connection terminals of the I/F circuit 120 and/or the logic die 100.

In a state in which the logic die 100 and the memory die 200 are not connected to each other, the test circuit 130 may test the defects of the I/F circuit 120 in advance by using the feedback test operation. In addition, by using the feedback test operation, in a state in which the logic die 100 is not connected to the memory die 200, the test circuit 130 may test in advance whether defects and/or shorts of the connection terminals for connecting the logic die 100 to the memory die 200, for example, through silicon vias (TSVs), through backside vias (TBVs), TSV pads, and/or TBV pads have occurred. Because the logic die 100 may perform the feedback test operation on the logic die 100 in advance of (e.g., before) the logic die 100 is connected to the memory die 200, the feedback test operation may be referred to as a “self-test operation” or a “self-feedback test operation”.

According to some embodiments, a defective logic die may be determined, by performing a feedback test on the logic die 100 before stacking the memory die 200 on the logic die 100, that is, before assembling and/or bonding the logic die 100 and the memory die 200. Accordingly, because defective logic dies are identified before good memory dies are stacked on the defective logic die, the connection of good memory dies to the defective logic die is preventable (or reduced), and therefore the yield of production for the semiconductor device 10 may be improved. In addition, compared to the case of testing the semiconductor device 10 while the logic die 100 and the memory die 200 are assembled, the test cost may also be reduced. In other words, logic dies identified as being defective may be discarded before being attached to a memory die, and/or may further processed to correct the defect before being attached to a memory die.

In at least one embodiment, the semiconductor device 10 may be provided as a high bandwidth memory HBM. In this case, for high-speed and low-power operations, the semiconductor device 10 may provide a wide interface structure of a multi-channel interface method between the logic die 100 and the memory die 200. For example, each of the plurality of core dies 200_1 through 200_N may support a 4-channel, and thus the memory die 200 may support a 16-channel. However, the inventive concepts are not limited thereto, and each of the plurality of core dies 200_1 through 200_N may also support 1-channel, 2-channel, 4-channel, or more.

In at least one embodiment, the logic die 100 and the plurality of core dies 200_1 through 200_N may communicate with each other via the TSVs and/or the TBVs. In addition, each of the plurality of core dies 200_1 through 200_N may include a plurality of channels that communicate with the logic die 100 independently of each other, and the TSVs and/or the TBVs may be physically separated from each other for the plurality of channels. For example, when the memory die 200 includes first through Ath channels CH1 through CHA, and each of the plurality of core dies 200_1 through 200_N includes two channels, A channels may correspond to 2*N channels (A is a natural number of 2 or more). In addition, when each of the plurality of core dies 200_1 through 200_N includes four channels, A channels may correspond to 4*N channels.

The I/F circuit 120 may include a plurality of input/output blocks for communication between the memory controller 110 and the memory die 200. Each input/output block may be connected to at least one TSV or at least one TBV, and may include at least one circuit for processing a signal transmitted via the connected TSV or TBV. In the inventive concepts, at least one embodiment, in which the memory controller 110 and the memory die 200 are transmitted via the plurality of TSVs is mainly described. Accordingly, the input/output block may be referred to as a “TSV circuit block”. However, the inventive concepts are not limited thereto, and the embodiments of the inventive concepts may be applied even when the memory controller 110 and the memory die 200 are transmitted via a plurality of TBVs.

According to some embodiments, the plurality of input/output blocks and/or a plurality of TSV circuit blocks may be implemented as macros or hard macros, and may be electrically connected to the plurality of TSVs. The hard macros may include various intellectual property (IP)s. The IPs may be referred to as blocks which are implemented to have a layout designed to perform an electrical function and an interconnection, and are reusable. Accordingly, the input/output block or the TSV circuit block may be referred to as a “TSV macro” or a “TSV slice”, respectively.

The semiconductor device 10 may be implemented to be included in a personal computer (PC), a mobile electronic device, a data server, etc. The mobile electronic device may be implemented as a laptop computer, a mobile phone, a smart phone, a tablet PC, a personal digital assistant (PDA), an enterprise digital assistant (EDA), a digital still camera, a digital video camera, a portable multi-media player (PMP), a personal navigation device or portable navigation device (PND), a hand-held game console, a mobile internet device (MID), a wearable computer, an internet of things (IoT) device, an internet of everything (IoE) device, a drone, and/or the like.

The logic die 100 may include an application specific integrated circuit (ASIC), a system on chip (SoC), an application processor (AP), a mobile AP, a chipset, or the like, or may include a device corresponding thereto. In addition, the logic die 100 may further include at least one of various components which function as a host, such as a central processing unit (CPU), a graphics processing unit (GPU), a neural processing unit (NPU), an accelerated processing unit (APU), a tensor processing unit (TPU), field programmable gate array (FPGA), a massively parallel processor array (MPPA), and a multi-processor system-on-chip (MPSoC).

The memory controller 110 may access the memory die 200 in response to a request by the host, and may communicate with the host by using various protocols. For example, the memory controller 110 may communicate with the host by using interface protocols, such as peripheral component interconnect-express (PCI-E), advanced technology attachment (ATA), serial ATA (SATA), parallel ATA (PATA), and serial attached (SA) small computer serial interface (SCSI) (SAS). In addition, various other interface protocols, such as a universal serial bus (USB), a multi-media card (MMC), enhanced small disk interface (ESDI), and integrated drive electronics (IDE), may be used as a protocol between the host and the memory controller 110.

The memory cell array MCA included in each of the plurality of core dies 200_1 through 200_N may include dynamic random access memory (RAM) (DRAM) cells, and in this case, the semiconductor device 10 may be referred to as HBM DRAM or HBM. For example, the memory cell array MCA may include double data rate (DDR) synchronous DRAM (SDRAM) (DDR SDRAM), low power DDR (LPDDR) SDRAM (LPDR SDRAM), graphics DDR (GDDR) SDRAM (GDDR SDRAM), rambus DRAM (RDRAM), etc. However, the inventive concepts are not limited thereto, and the memory cell array MCA may include a volatile memory such as SRAM or a non-volatile memory, such as flash memory, magnetic RAM (MRAM), ferroelectric RAM (FeRAM), phase change RAM (PRAM), and respective RAM (ReRAM).

In addition, each of the plurality of core dies 200_1 through 200_N may further include periphery circuits for controlling a write operation and a read operation on/from the memory cell array MCA. In some embodiments, each of the plurality of core dies 200_1 through 200_N may further include a computation circuit which performs computation processing by using data received from the logic die 100.

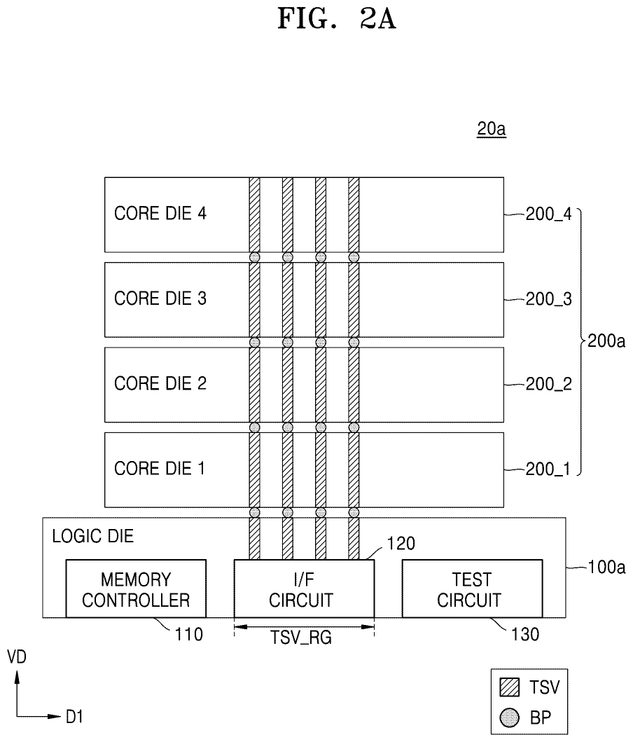

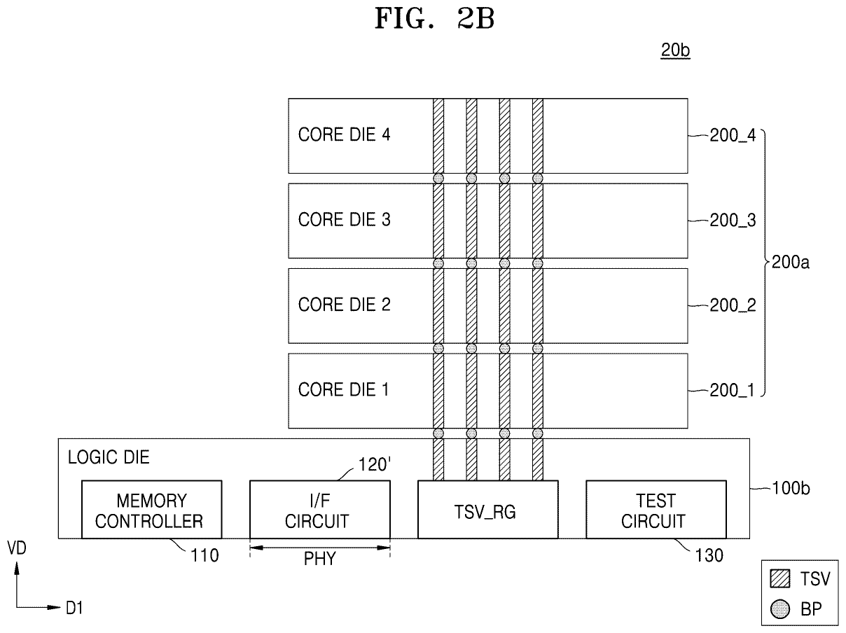

FIG. 2A illustrates a structure of a semiconductor device 20a according to at least one embodiment.

Referring to FIG. 2A, the semiconductor device 20a may include a logic die 100a and a memory die 200a, and the memory die 200a may include first through fourth core dies 200_1 through 200_4 stacked on the logic die 100a in a vertical direction VD. According to the embodiment, the semiconductor device 20a may be referred to as a three-dimensional (3D) memory device or a stack-type memory device. For example, the semiconductor device 20a may correspond to a 3D HBM device. The semiconductor device 20a may correspond to an implementation example of the semiconductor device 10 of FIG. 1, and the descriptions given above with reference to FIG. 1 may also be applied to the present embodiment.

Each of the logic die 100a and the first through fourth core dies 200_1 through 200_4 may include the through silicon vias TSVs. The through silicon vias TSVs in the logic die 100a may penetrate the logic die 100a and extend in the vertical direction VD, and the through silicon vias TSVs of each of the first through fourth core dies 200_1 through 200_4 may penetrate each of the first through fourth core dies 200_1 through 200_4 and extend in the vertical direction VD. Bumps BP may be arranged between the logic die 100a and the first through fourth core dies 200_1 through 200_4. For example, the bumps BP may include micro-bumps. For example, the bumps BP may include conductive bumps including copper, cobalt, nickel, etc. The logic die 100a and the first through fourth core dies 200_1 through 200_4 may be electrically connected to each other via the through silicon vias TSVs and the bumps BP.

The logic die 100a may further include the memory controller 110, then I/F circuit 120, and the test circuit 130. The through silicon vias TSVs in the logic die 100a may be disposed in a TSV region TSV_RG, and the I/F circuit 120 may be arranged to be connected to the through silicon vias TSVs in the TSV region TSV_RG. For example, the I/F circuit 120 may be arranged below the through silicon vias TSVs in the TSV region TSV_RG, and as a result, the I/F circuit 120 may be electrically connected to the first through fourth core dies 200_1 through 200_4 via the through silicon vias TSVs.

In addition, the logic die 100a may further include backside vias, for example, the through backside vias TBVs. For example, the through backside vias TBVs may be arranged to be connected to the I/F circuit 120 in the TSV region TSV_RG. As a result, the I/F circuit 120 may be electrically connected to the first through fourth core dies 200_1 through 200_4 via the through backside vias TBVs and/or wires connected to the through backside vias TBVs. Furthermore, the I/F circuit 120 may be electrically connected to other components within the logic die 100a, for example, the memory controller 110 and the test circuit 130 via the through backside vias TBVs, or may also be connected to an external device.

FIG. 2B illustrates a structure of a semiconductor device 20b according to at least one embodiment.

Referring to FIG. 2B, the semiconductor device 20b may correspond to a modified example of the semiconductor device 20a of FIG. 2A, and the descriptions given above with reference to FIG. 2A may also be applied to the present embodiment. The semiconductor device 20b may include a logic die 100b and the memory die 200a, and the logic die 100b may include the memory controller 110, an I/F circuit 120′, the test circuit 130, and a plurality of through silicon vias TSV. According to the at least one embodiment, the I/F circuit 120′ may be arranged in a physical region PHY adjacent to the TSV region TSV_RG. For example, the I/F circuit 120′ may be arranged between the memory controller 110 and the TSV region TSV_RG, but the examples are not limited thereto.

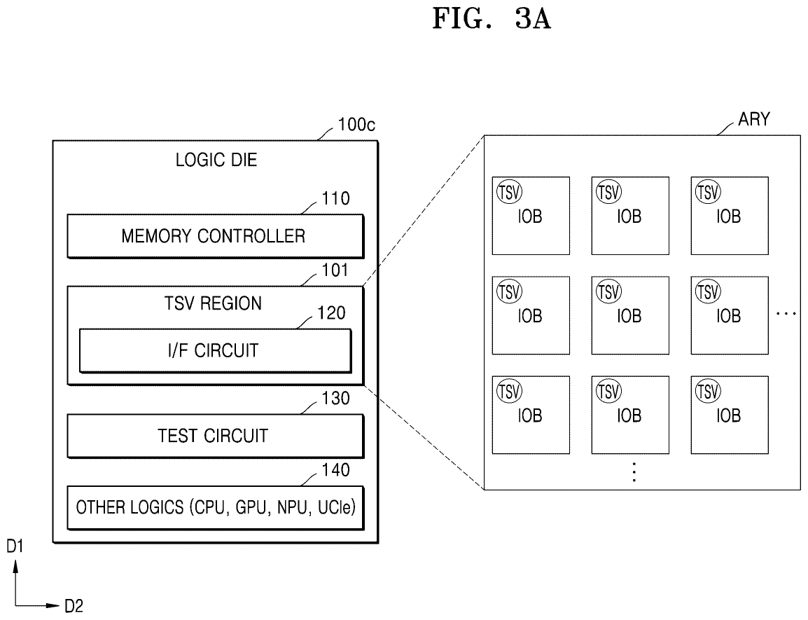

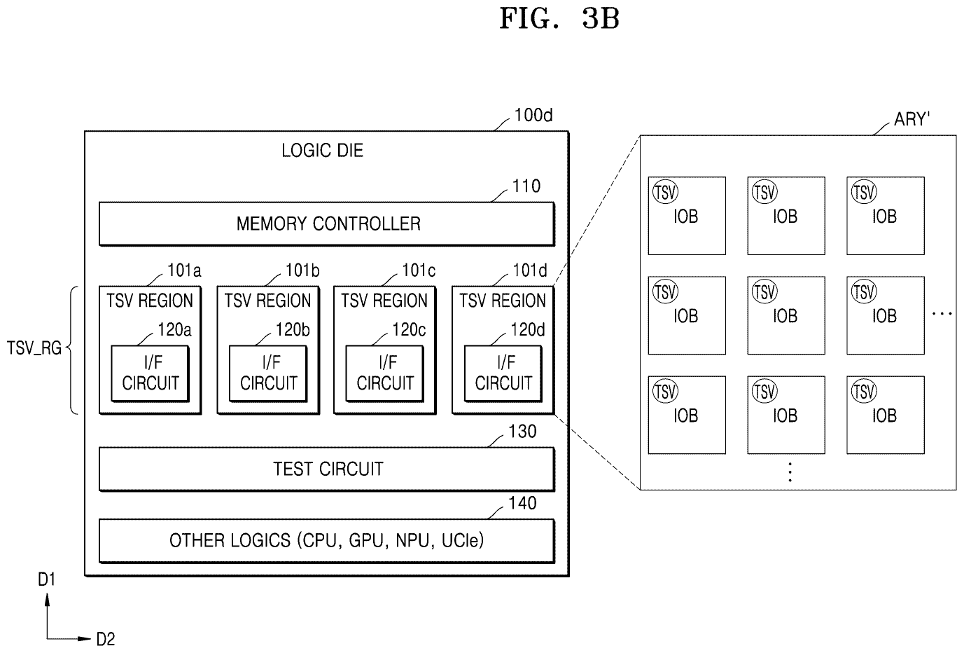

FIG. 3A illustrates a logic die 100c according to at least one embodiment.

Referring to FIG. 3A, the logic die 100c may include a TSV region 101, the memory controller 110, the test circuit 130, and other logics 140. In this case, the logic die 100c may correspond to an example of the logic die 100a in FIG. 2A, and the TSV region 101 may correspond to the TSV region TSV_RG in FIG. 2. Descriptions given with reference to FIGS. 1 and 2A may also be applied to the present embodiment. Although FIG. 3A illustrates that the memory controller 110, the I/F circuit 120, the test circuit 130, and the other logics 140 are arranged in a first direction D1, the inventive concepts are not limited thereto. According to some embodiments, the arrangement of the memory controller 110, the I/F circuit 120, the test circuit 130, and the other logics 140 in the logic die 100c may be variously changed.

In at least one embodiment, the other logics 140 may include core logics, such as CPU, GPU, and NPU. In at least one embodiment, the other logics 140 may include interface logics. For example, the interface logics may include a universal chip interconnect express (UCIe) module, or the like to support interface protocols between semiconductor chips or semiconductor dies.

The logic die 100c may further include a plurality of TSVs and the I/F circuit 120 arranged in the TSV region 101, and the I/F circuit 120 may include a plurality of input/output blocks IOB or a plurality of TSV macros. Each input/output block IOB may be connected to at least one through silicon via TSV. Although FIG. 3A illustrates that each input/output block IOB is connected to one through silicon via TSV, the inventive concepts are not limited thereto. According to some embodiments, each input/output block IOB may also be connected to a plurality of through silicon vias TSV.

In at least one embodiment, the I/F circuit 120 may include an input/output block array ARY. For example, a plurality of TSVs may be arranged in an array form in the first direction D1 and a second direction D2, and in addition, a plurality of input/output blocks IOB may also be arranged in an array form in the first and second directions D1 and D2. Accordingly, the plurality of input/output blocks IOB may constitute the input/output block array ARY. According to some embodiments, in the input/output block array ARY, the size of each input/output block IOB an interval between adjacent input/output blocks IOB may be variously changed.

FIG. 3B illustrates a logic die 100d according to at least one embodiment.

Referring to FIG. 3B, the logic die 100d may correspond to a modified example of the logic die 100c in FIG. 3A. The TSV region TSV_RG of the logic die 100d may include first through fourth TSV regions 101a through 101d. The plurality of through silicon vias TSV and a plurality of input/output blocks IOB may be arranged in each of the first through fourth TSV regions 101a through 101d. However, the inventive concepts are not limited thereto, and the TSV region TSV_RG may be divided into five or more TSV regions, or less than four TSV regions.

Each of the first through fourth TSV regions 101a through 101d may correspond to a plurality of channels. For example, each of the first through fourth TSV regions 101a through 101d may correspond to four channels. For example, a first TSV region 101a may include an I/F circuit 120a corresponding to two channels of the first core die (for example, 200_1 in FIG. 2A) and two channels of the third core die (for example, 200_3 in FIG. 2A). For example, a second TSV region 101b may include an I/F circuit 120b corresponding to two channels of the second core die (for example, 200_2 in FIG. 2A) and two channels of the fourth core die (for example, 200_4 in FIG. 2A). For example, a third TSV region 101c may include an I/F circuit 120c corresponding to the other two channels of the first core die 200_1 and the other two channels of the third core die 200_3. For example, a fourth TSV region 101d may include an I/F circuit 120d corresponding to the other two channels of the second core die 200_2 and the other two channels of the fourth core die 200_4. The I/F circuit arranged in each of the first through fourth TSV regions 101a through 101d may include an input/output block array. For example, the I/F circuit 120d arranged in the fourth TSV region 101d may include an input/output block array ARY' in which the plurality of input/output blocks IOB are arranged in an array form.

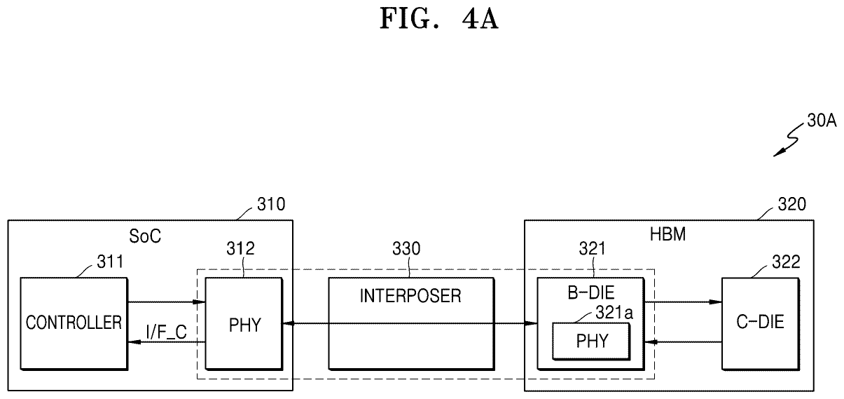

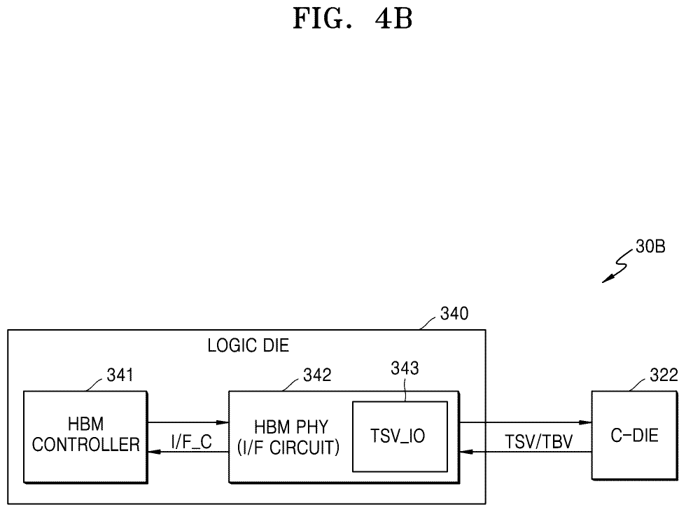

FIG. 4A illustrates an HBM system 30A according to at least one embodiment.

Referring to FIG. 4A, the HBM system 30A may include a system-on-chip (SoC) 310 and an HBM 320, and the HBM 320 may include a base die B-DIE 321 and a plurality of core dies C-DIE 322 arranged on the B-DIE 321. In this case, the SoC 310 and the HBM 320 may be mounted on an interposer 330. For example, the HBM 320 may correspond to the semiconductor device 10 of FIG. 1, the semiconductor device 20a of FIG. 2A, or the semiconductor device 20b of FIG. 2B, and descriptions given above with reference to FIGS. 1 through 3B may be applied to the present embodiment. Accordingly, before the B-DIE 321 and the plurality of C-DIEs 322 are assembled or bonded, the feedback test operation on the B-DIE 321 may be performed, and as a result, whether defects in a PHY 321a or shorts between the through silicon vias TSV and/or the through backside vias TBV occur may be determined in advance.

The SoC 310 may include a controller 311 and a PHY 312, and the controller 311 and the PHY 312 may exchange command/address and data via a controller interface I/F_C such as a DDR PHY interface (DFI). The PHY 312 may communicate with the PHY 321a provided in the B-DIE 321 of the HBM 320 via the interposer 330. For example, the SoC 310 and the HBM 320 may exchange command/address and data via the interposer 330 based on high-speed communication according to the Joint Electron Device Engineering Council (JEDEC) interface.

FIG. 4B illustrates an HBM device 30B according to at least one embodiment.

Referring to FIG. 4B, the HBM device 30B may include a logic die 340 and the plurality of core dies C-DIE 322. For example, the HBM device 30B may correspond to the semiconductor device 10 of FIG. 1, the semiconductor device 20a of FIG. 2A, or the semiconductor device 20b of FIG. 2B, and descriptions given above with reference to FIGS. 1 through 3B may be applied to the present embodiment.

The logic die 340 may include an HBM controller 341 and an HBM PHY 342. The HBM controller 341 and the HBM PHY 342 may exchange command/address and data according to the controller interface I/F_C such as DFI. A plurality of core dies C-DIE 322 may be stacked on the logic die 340, and accordingly, the HBM PHY 342 may be referred to as a 3D HBM PHY. The HBM controller 341 may correspond to the memory controller 110 in FIG. 1, and the HBM PHY 342 may correspond to the I/F circuit 120 in FIG. 1. Accordingly, before the logic die 340 and the plurality of core dies C-DIE 322 are assembled or bonded, the feedback test operation on the logic die 340 may be performed, and as a result, whether defects in HBM PHY 342 or shorts between through silicon vias and/or through backside vias TSV/TBV occur may be determined in advance.

Unlike FIG. 4A, the HBM device 30B may not include the SoC 310, the interposer 330, and the B-DIE 321. The HBM PHY 342 may perform functions of the PHY 312 included in the SoC 310, the interposer 330, and the PHY 321a included in the B-DIE 321 of the HBM 320 in FIG. 4A. Accordingly, there is no need to perform JEDEC interface-based high-speed communication via an interposer in transmitting command/address and data from the HBM controller 341 to the plurality of core dies C-DIE 322. As the HBM PHY 342 of the logic die 340 communicates with the plurality of core dies C-DIE 322 via the TSV/TBV, the HBM PHY 342 of the logic die 340 may include a TSV input/output circuit (I/O) 343. For example, the TSV I/O 343 may include transmitters and receivers connected to the TSV/TBV.

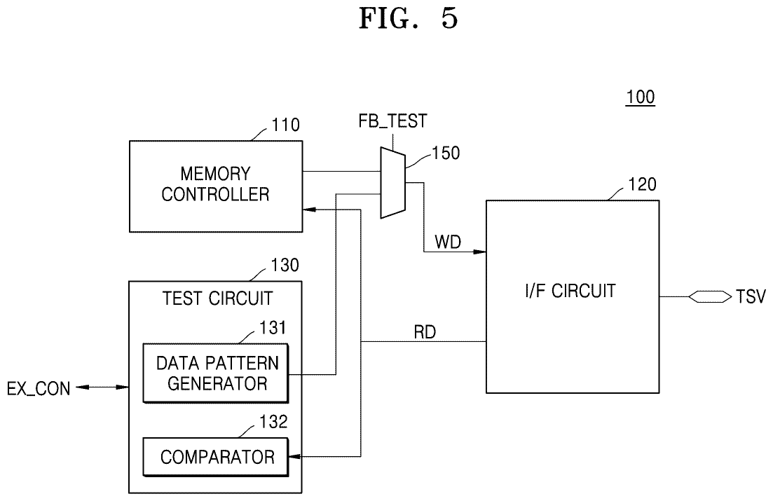

FIG. 5 is a detailed block diagram of the logic die 100 according to at least one embodiment.

Referring to FIGS. 1 and 5 together, the logic die 100 may include the memory controller 110, the I/F circuit 120, the test circuit 130, and a selection circuit 150. The memory controller 110 may control a memory operation, such as a write operation and a read operation, on the memory die 200. For example, during the write operation on the memory die 200, the memory controller 110 may transmit a write data WD to the memory die 200 via the I/F circuit 120 and the through silicon via TSV. For example, during the read operation on the memory die 200, the memory controller 110 may receive a read data RD from the memory die 200 via the through silicon via TSV and the I/F circuit 120.

The test circuit 130 may control a feedback test operation on the logic die 100. In the embodiment, the test circuit 130 may control a feedback test operation on the logic die 100 according to an external control signal EX_CON. However, the inventive concepts are not limited thereto, and the test circuit 130 may control a feedback test operation on the logic die 100 under the control of the memory controller 110. Furthermore, in some embodiments, the logic die 100 may not include the test circuit 130, and in this case, the memory controller 110 may control a feedback test operation on the logic die 100.

In the embodiment, the test circuit 130 may include a data pattern generator 131 and a comparator 132. The data pattern generator 131 may be configured to generate a data pattern for a feedback test operation and/or a self-test operation on the logic die 100. For example, the data pattern generator 131 may be referred to as being configured to generate test data. The generated test data may be provided to the I/F circuit 120 as the write data WD. For example, the data pattern generator 131 may generate the data patterns or test data based on the external control signal EX_CON.

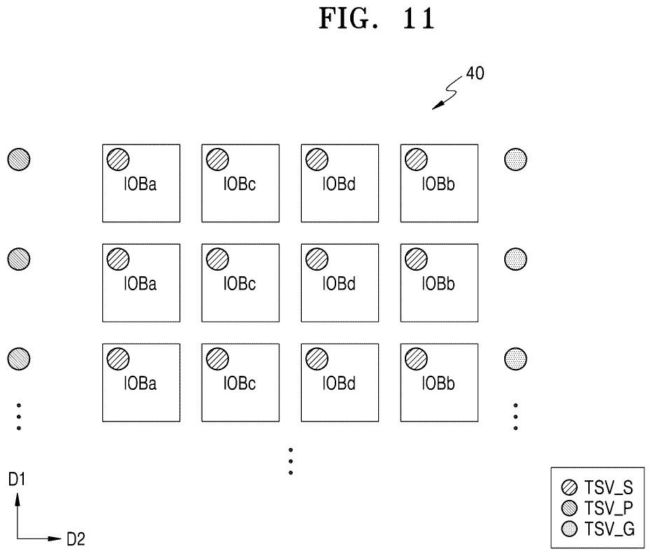

For example, to test whether a short circuit occurs between a target TSV and a power TSV (for example, TSV_P in FIG. 11), the data pattern generator 131 may generate test data ‘0’ having a ground voltage level. For example, to test whether a short circuit occurs between the target TSV and a ground TSV (for example, TSV_G in FIG. 11), the data pattern generator 131 may generate test data ‘1’ having a power supply voltage level. For example, to test whether a short circuit has occurred between a first TSV and a second TSV, the data pattern generator 131 may differently generate first test data applied to the input/output block IOB connected to the first TSV and second test data applied to the input/output block IOB connected to the second TSV.

The comparator 132 may receive data feedbacked (or returned, or fed back) to the test data from the I/F circuit 120 (e.g., result data and/or test result data). The feedback data may be configured to output by the I/F circuit 120 as the read data RD. The comparator 132 may be configured to compare the test data generated by the data pattern generator 131 with the result data received from the I/F circuit 120 (e.g., the feedback data by the I/F circuit 120). As a result of the comparison, when the test data and the feedback data are the same (and/or match), the logic die 100 be determined to have no defect. As a result of the comparison, when the test data and the feedback data are the not same (e.g., do not match), the logic die 100 may be determined to have a defect.

The selection circuit 150 may include a first input terminal connected to the memory controller 110 and a second input terminal connected to the test circuit 130. The selection circuit 150 may select the first input terminal or the second input terminal according to a control signal. For example, the selection circuit 150 may include a multiplexer. In the embodiment, the selection circuit 150 may select an output signal of the memory controller 110 or an output signal of the test circuit 130 according to a control signal, for example, a feedback test enable signal FB_TEST, and may provide the selected output signal to the I/F circuit 120 as the write data WD.

In the embodiment, the feedback test enable signal FB_TEST may be generated by the memory controller 110. In the embodiment, the feedback test enable signal FB_TEST may be generated in the test circuit 130. In the embodiment, the feedback test enable signal FB_TEST may be provided as the external control signal EX_CON. In at least one embodiment, the feedback test enable signal FB_TEST may be generated by other logics (for example, CPU, GPU, NPU, or the like in FIG. 3A).

In the embodiment, the feedback test enable signal FB_TEST may have an enable level (for example, a logic high level) in the feedback test mode for the logic die 100, and may have a disable level (for example, a logic low level) in an operation mode, for example, in a write mode or a read mode of the memory die 200. For example, when the feedback test enable signal FB_TEST is at the enable level, the selection circuit 150 may select the test data generated by the data pattern generator 131 of the test circuit 130, and may provide the selected test data to the I/F circuit 120 as the write data WD. For example, when the feedback test enable signal FB_TEST is at the disabled level, the selection circuit 150 may select a signal provided by the memory controller 110, for example, a command, an address, data, and/or a clock signal, and may provide the selected signal to the I/F circuit 120 as the write data WD.

When the logic die 100 is connected to the memory die 200, the I/F circuit 120 may be used as a write path and/or a read path to the memory die 200. During the write operation on the memory die 200, the I/F circuit 120 may transmit the write data WD received from the memory controller 110 to the memory die 200 via the through silicon via TSV. In addition, during the read operation on the memory die 200, the I/F circuit 120 may transmit data received via through silicon via TSV from the memory die 200 to the memory controller 110 as the read data RD.

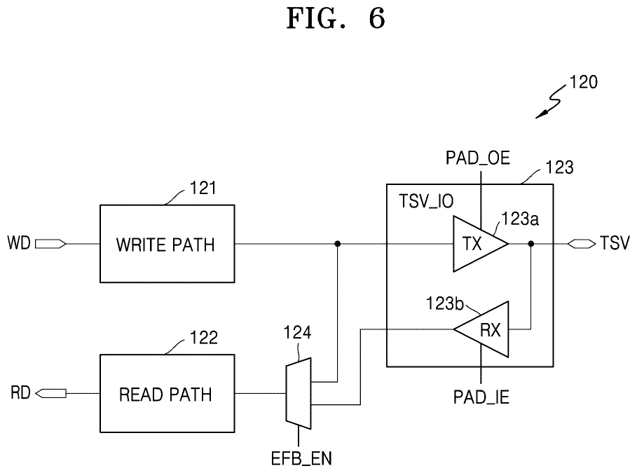

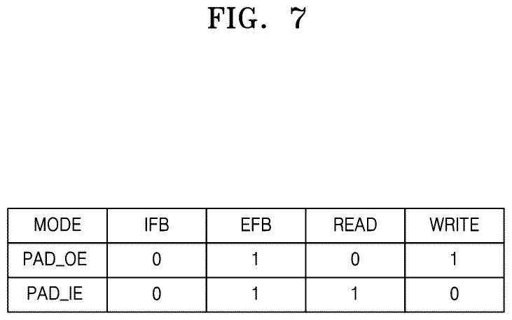

When the logic die 100 is not connected to the memory die 200, the feedback test and/or the self-test on the logic die 100 may be performed, and in this case, the I/F circuit 120 may be used as a feedback test path or a self-test path for the logic die 100. During the feedback test operation on the logic die 100, the I/F circuit 120 may receive the test data from the test circuit 130 as the write data WD, and the received test data may be feedbacked (or “fed back”) to the test circuit 130. However, the inventive concepts are not limited thereto, and during the feedback test operation on the logic die 100, the I/F circuit 120 may receive the test data from the memory controller 110 as the write data WD, and the received test data may also be feed back to the memory controller 110. The feedback test operation on the I/F circuit 120 is described in more detail with reference to FIGS. 6 through 7B.

FIG. 6 is a block diagram of the I/F circuit 120 according to at least one embodiment. FIG. 7 shows a table representing a transmission enable signal PAD_OE and a receiving enable signal PAD_IE per operation mode, according to at least one embodiment.

Referring to FIGS. 1, 6, and 7 together, the I/F circuit 120 may include a write path 121, a read path 122, a TSV input/output circuit 123, and a selector 124. The TSV input/output circuit 123 may include a transmitter 123a and a receiver 123b. In some embodiments, the I/F circuit 120 may include the plurality of input/output blocks IOB respectively connected to plurality of TSV macros, for example, the plurality of TSV macros. Each input/output block IOB may perform the input/output operation on a signal transmitted via, e.g., a connected TSV, and may be implemented as illustrated in FIG. 6. Thus, the configuration of the I/F circuit 120 described hereinafter may be applied to each input/output block IOB or each TSV macro included in the I/F circuit 120.

The I/F circuit 120 may be configured to operate in the feedback test mode in which the feedback test operation on the logic die 100 is performed, in a read mode READ in which a read operation on the memory die 200 is performed, and/or in a write mode WRITE in which a write operation on the memory die 200 is performed. For example, in at least some embodiments, the I/F circuit 120 may be configured to switch between the feedback test mode, the read mode, and/or the write mode, based, e.g., on a command and/or enable signal. In some cases, the feedback test mode, in which the feedback test operation on the logic die 100 is performed, may include an internal feedback test mode IFB and/or a first test mode, in which the internal feedback test operation is performed, and an external feedback test mode EFB or a second test mode, in which the external feedback operation is performed.

The “internal feedback test operation” may be defined as a test operation in which the test data provided to the I/F circuit 120 is feedback via the write path 121 and the read path 122. In the internal feedback test mode IFB, the test data may be fed back via the write path 121, the selector 124, and the read path 122. In the internal feedback test mode IFB, both the transmission enable signal PAD_OE and the receiving enable signal PAD_IE may have a disable level (for example, a logic low level), and accordingly, both the transmitter 123a and the receiver 123b may be disabled.

The “external feedback test operation” may be defined as a test operation in which the test data provided to the I/F circuit 120 is feedback via the write path 121, the TSV input/output circuit 123, the through silicon via TSV, and the read path 122. In the external feedback test mode EFB, the test data may be fed back via the write path 121, the transmitter 123a, the through silicon via TSV, the receiver 123b, the selector 124, and the read path 122. In the external feedback test mode EFB, both the transmission enable signal PAD_OE and the receiving enable signal PAD_IE may have an enable level (for example, a logic high level), and accordingly, both the transmitter 123a and the receiver 123b may be enabled.

In the read mode READ, the transmission enable signal PAD_OE may have a disable level (for example, a logic low level), and the receiving enable signal PAD_IE may have an enable level (for example, a logic high level). Accordingly, the transmitter 123a may be disabled, and the receiver 123b may be enabled. In the write mode WRITE, the transmission enable signal PAD_OE may have an enable level (for example, a logic low level), and the receiving enable signal PAD_IE may have a disable level (for example, a logic high level). Accordingly, the transmitter 123a may be enabled, and the receiver 123b may be disabled.

The write path 121 may generate output data or an output signal, by receiving the write data WD and performing a signal processing on the received write data WD. The write path 121 may provide the generated output data or output signal to the transmitter 123a or the selector 124. In the embodiment, the write path 121 may perform a signal processing for transmitting the write data WD to the memory die 200. For example, the write path 121 may include flip-flops, buffers, serialization circuits, delay control logics, and/or level shifters.

The transmitter 123a may be enabled according to an output enable signal PAD_OE. When the output enable signal PAD_OE is at an enable level (for example, a logic high level), the transmitter 123a may be enabled, and when the output enable signal PAD_OE is at a disable level (for example, a logic low level), the transmitter 123a may be disabled. For example, when the output enable signal PAD_OE is at an enable level, the transmitter 123a may provide the output data or an output signal, which is received from the write path 121.

The receiver 123b may be enabled according to an input enable signal PAD_IE. When the input enable signal PAD_IE is at an enable level (for example, a logic high level), the receiver 123b may be enabled, and when the input enable signal PAD_IE is at a disable level (for example, a logic low level), the receiver 123b may be disabled. For example, when the input enable signal PAD_IE is at an enable level, the receiver 123b may provide input data or an input signal, which is received from the through silicon via TSV, to the selector 124.

The selector 124 may include the first input terminal connected to the write path 121 and the second input terminal connected to the TSV input/output circuit 123. Accordingly, the selector 124 may receive the output signal of the write path 121 via the first input terminal, and the output signal of the receiver 123b via the second input terminal. For example, the selector 124 may include a multiplexer. The selector 124 may select an output signal of the write path 121 or an output signal of the receiver 123b according to a control signal, for example, an external feedback test enable signal EFB_EN, and may provide the selected output signal to the read path 122.

In at least one embodiment, the external feedback test enable signal EFB_EN may be generated by the memory controller 110. For example, the external feedback test enable signal EFB_EN may be generated in the test circuit 130. The external feedback test enable signal EFB_EN may be provided as the external control signal EX_CON. In at least some embodiments, the external feedback test enable signal EFB_EN may be generated by other logics (for example, CPU, GPU, NPU, or the like in FIG. 3A).

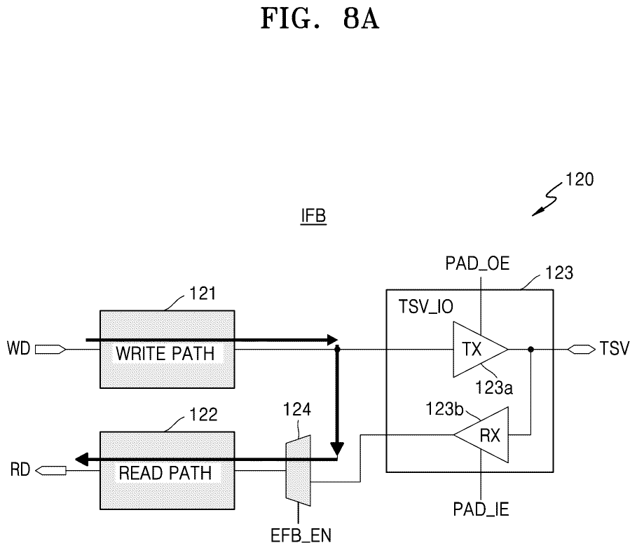

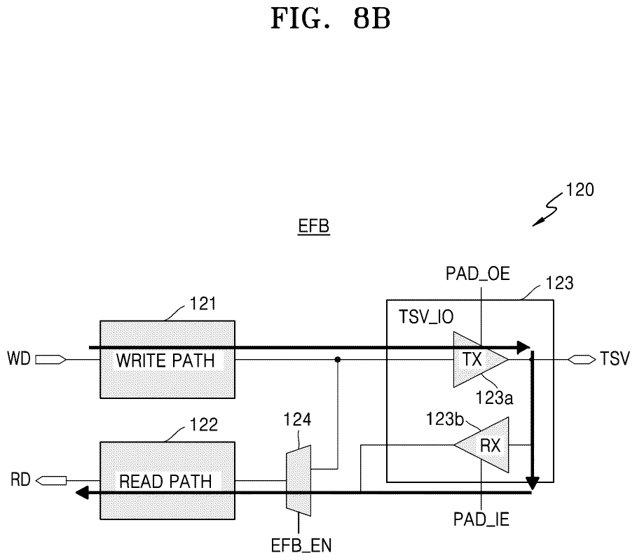

In at least one embodiment, when the internal feedback test operation is performed on the logic die 100, the external feedback test enable signal EFB_EN may be disabled. When the external feedback test enable signal EFB_EN is at a disable level, the selector 124 may provide an output signal of the write path 121 to the read path 122. This issue is described in more detail with reference to FIG. 8A.

In at least one embodiment, when the external feedback test operation is performed on the logic die 100, the external feedback test enable signal EFB_EN may be enabled. When the external feedback test enable signal EFB_EN is at an enable level, the selector 124 may provide an output signal of the receiver 123b to the read path 122. This issue is described in more detail with reference to FIG. 8B.

FIG. 8A shows an operation of the I/F circuit 120 in the internal feedback test mode IFB according to at least one embodiment.

Referring to FIGS. 1, 7, and 8A together, in the internal feedback test mode IFB of the logic die 100, both the transmission enable signal PAD_OE and the receiving enable signal PAD_IE may be at a disable level, and accordingly, the transmitter 123a and the receiver 123b may be disabled. In addition, in the internal feedback test mode IFB, the external feedback test enable signal EFB_EN may be at a disable level, and accordingly, the selector 124 may select the output signal of the write path 121.

For example, in the internal feedback test mode IFB, a feedback loop including the write path 121, the selector 124, and the read path 122 may be generated. Thus, the test data generated by the data pattern generator 131 of the test circuit 130 may be input to the write path 121 as the write data WD, and the test data may be fed back to the test circuit 130 via the write path 121, the selector 124, and the read path 122. The result data output by the read path 122 may be provided to the comparator 132 of the test circuit 130 as the read data RD.

FIG. 8B shows an operation of the I/F circuit 120 in the external feedback test mode EFB according to at least one embodiment.

Referring to FIGS. 1, 7, and 8A together, in the external feedback test mode EFB of the logic die 100, both the transmission enable signal PAD_OE and the receiving enable signal PAD_IE may be at an enable level, and accordingly, the transmitter 123a and the receiver 123b may be enabled. In addition, in the external feedback test mode EFB, the external feedback test enable signal EFB_EN may be at an enable level, and accordingly, the selector 124 may select the output signal of the receiver 123b.

For example, in the external feedback test mode EFB, a feedback loop including the write path 121, the transmitter 123a, the through silicon via TSV, the receiver 123b, the selector 124, and the read path 122 may be generated. Accordingly, the test data generated by the data pattern generator 131 of the test circuit 130 may be input to the write path 121 as the write data WD, and the test data may be fed back to the test circuit 130 via the write path 121, the transmitter 123a, the through silicon via TSV, the receiver 123b, the selector 124, and the read path 122. The result data output by the read path 122 may be provided to the comparator 132 of the test circuit 130 as the read data RD.

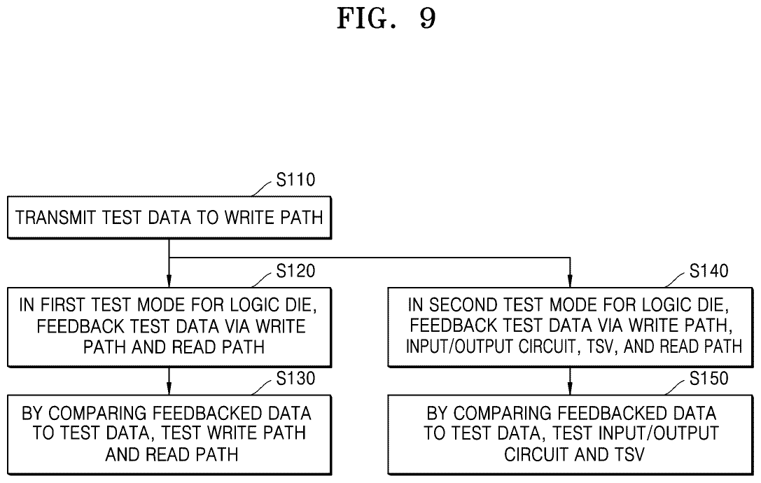

FIG. 9 is a flowchart of a method of feedback testing of a logic die, according to at least one embodiment.

Referring to FIG. 9, the method of feedback testing of a logic die according to the inventive concepts may include a method of testing whether defects of an internal circuit of the logic die and/or shorts between through silicon vias TSV have occurred, before the logic die is connected to a memory die. For example, the method of feedback testing of the logic die may be performed on the logic die 100 in FIG. 1, and is described below with reference to FIGS. 1, 5, 6, and 9 together.

In operation S110, the logic die 100 transmits the test data to the write path 121. For example, the data pattern generator 131 of the test circuit 130 may generate the test data, and transmit the generated test data to the write path 121. For example, when the feedback test enable signal FB_TEST is at the enable level, the selection circuit 150 may transmit the test data output by the data pattern generator 131 to the write path 121 of the I/F circuit 120.

In operation S120, in the first test mode of the logic die 100, the test data is fed back via the write path 121 and the read path 122. For example, the first test mode may correspond to an internal feedback test mode (for example, IFB in FIG. 8A). In operation S130, the logic die 100 tests the write path 121 and the read path 122 by comparing the feedback data with the test data. In addition, in the first test mode, the test data may be fed back via the write path 121, the selector 124, and the read path 122, and accordingly, the selector 124 may also be tested. This fed back test data may also be referred to as feedback test data and/or first test mode feedback data.

In operation S140, in the second test mode of the logic die 100, the test data is fed back via the write path 121, the TSV input/output circuit 123, the through silicon via TSV, and the read path 122. For example, the second test mode may correspond to an external feedback test mode (for example, EFB in FIG. 8B). In operation S150, the TSV input/output circuit 123 and the through silicon via TSV are tested by comparing the feedback data with the test data. In addition, in the second test mode, the test data may be fed back via the write path 121, the TSV input/output circuit 123, the through silicon via TSV, the selector 124, and the read path 122, and accordingly, the selector 124 may also be tested. This fed back test data may also be referred to as feedback test data and/or second test mode feedback data.

According to at least embodiment, operations S120 and S130 may be performed first, followed by operations S140 and S150. According to the embodiment, operations S140 and S150 may be performed first, followed by operations S120 and S130. According to the embodiment, operations S120 and S130 and operations S140 and S150 may be selectively performed. For example, operations S120 and S130 may be omitted, while operations S140 and S150 may be performed.

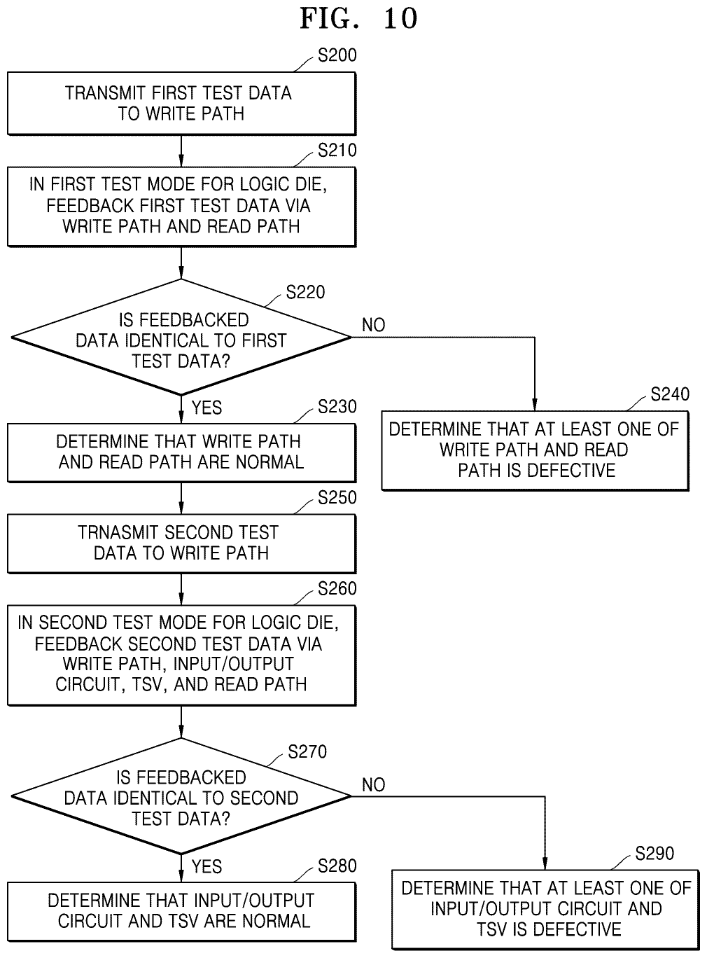

FIG. 10 is a flowchart of a method of feedback testing of a logic die, according to at least one embodiment.

Referring to FIG. 10, a method of feedback testing of a logic die according to the inventive concepts may include a method of testing whether defects of the internal circuit and/or shorts between the through silicon vias TSV in the logic die has occurred, before the logic die is connected to a memory die. For example, a method of feedback testing of a logic die according to the inventive concepts may correspond to the embodiment of the feedback test method of FIG. 9. For example, a method of feedback testing of a logic die may be performed on the logic die 100 in FIG. 1, and is described below with reference to FIGS. 1, 5, 6, and 10 together.

In operation S200, the logic die 100 transmits the first test data to the write path 121. For example, the data pattern generator 131 of the test circuit 130 may generate the first test data, and transmit the generated first test data to the write path 121. For example, when the feedback test enable signal FB_TEST is at the enable level, the selection circuit 150 may transmit the first test data output by the data pattern generator 131 to the write path 121 of the I/F circuit 120.

In operation S210, in the first test mode of the logic die 100, the first test data is fed back via the write path 121 and the read path 122. For example, the first test mode may correspond to an internal feedback test mode (for example, IFB in FIG. 8A). In operation S220, the logic die 100 determines whether the feedback data is the same as the first test data. For example, the comparator 132 of the test circuit 130 may determine whether the feedback data and the first test data are the same.

As a result of the determination, when the feedback data is the same as the first test data, in operation S230, the logic die 100 may determine that the write path 121 and the read path 122 are normal. In addition, in operation S230, the logic die 100 determines that the selector 124 is also normal. On the other hand, as a result of the determination, when the feedback data is not the same as the first test data, in operation S240, the logic die 100 determines that at least one of the write path 121 and the read path 122 is defective.

When the write path 121 and the read path 122 are normal as a result of the first test, in operation S250, the logic die 100 transmits the second test data to the write path 121. For example, the data pattern generator 131 of the test circuit 130 may generate the second test data, and transmit the generated second test data to the write path 121. For example, when the feedback test enable signal FB_TEST is at the enable level, the selection circuit 150 may transmit the second test data output by the data pattern generator 131 to the write path 121 of the I/F circuit 120.

In operation S260, in the second test mode of the logic die 100, the second test data is fed back via the write path 121, the TSV input/output circuit 123, the through silicon via TSV, and the read path 122. For example, the second test mode may correspond to an external feedback test mode (for example, EFB in FIG. 8B). In operation S270, the logic die 100 determines whether the feedback data is the same as the second test data. For example, the comparator 132 of the test circuit 130 may determine whether the feedback data and the second test data are the same.

As a result of the determination, when the feedback data is the same as the second test data, in operation S280, the logic die 100 determines that the TSV input/output circuit 123 and the through silicon via TSV are normal. On the other hand, as a result of the determination, when the feedback data is not the same as the second test data, in operation S290, the logic die 100 determines that at least one of the TSV input/output circuit 123 and the through silicon via TSV is defective.

The logic die determined as normal in operations S230 and S280 may be connected to the memory die, and the logic die determined as defective in operations S240 or S290 may not be connected to the memory die. Because it is possible to prevent a defective logic die from being connected to a memory die, the yield of a semiconductor device including the logic die and the memory die may be improved. In addition, because it is possible to determine whether the logic die is defective in advance, the test cost of the semiconductor device may be reduced.

FIG. 11 illustrates a logic die 40 including a TSV array according to at least one embodiment.

Referring to FIG. 11, the logic die 40 may include the plurality of through silicon vias TSV arranged in the TSV region (for example, 101 in FIG. 3A), and the plurality of through silicon vias TSV may be arranged in an array form in the first and second directions D1 and D2. For example, the plurality of through silicon vias TSV may include signal TSVs TSV_S, in which signals are transmitted to/from the logic die 40 and memory die, power TSVs TSV_P receiving a power voltage, and ground TSVs TSV_G receiving a ground voltage. For example, the power TSVs TVS_P may be arranged in a line in the first direction D1, but the inventive concepts are not limited thereto. For example, the ground TSVs TSV_G may be arranged in a line in the first direction D1, but the inventive concepts are not limited thereto. The arrangement of the signal TSVs TSV_S, the power TSVs TSV_P, and the ground TSVs TSV_G may be variously changed according to at least one embodiment.

The logic die 40 may further include the plurality of input/output blocks IOB respectively connected to the signal TSVs TSV_S. For example, the plurality of input/output blocks IOB may include first input/output blocks IOBa, second input/output blocks IOBb, third input/output blocks IOBc, and fourth input/output blocks IOBd. For example, each of the first through fourth input/output blocks IOBa through IOBd may transceive different signals. For example, the first input/output blocks IOBa may be respectively connected to TSV_CA/RAs, through which the column/row address CA/RA is transmitted from the logic die 40 to the memory die. For example, the second input/output blocks IOBb may be respectively connected to TSV_CKs, through which the clock signal CK is transmitted from the logic die 40 to the memory die. For example, the third and fourth input/output blocks IOBc and IOBd may be respectively connected to TSV_DQs, through which data DQ is transmitted between the logic die 40 and the memory die.

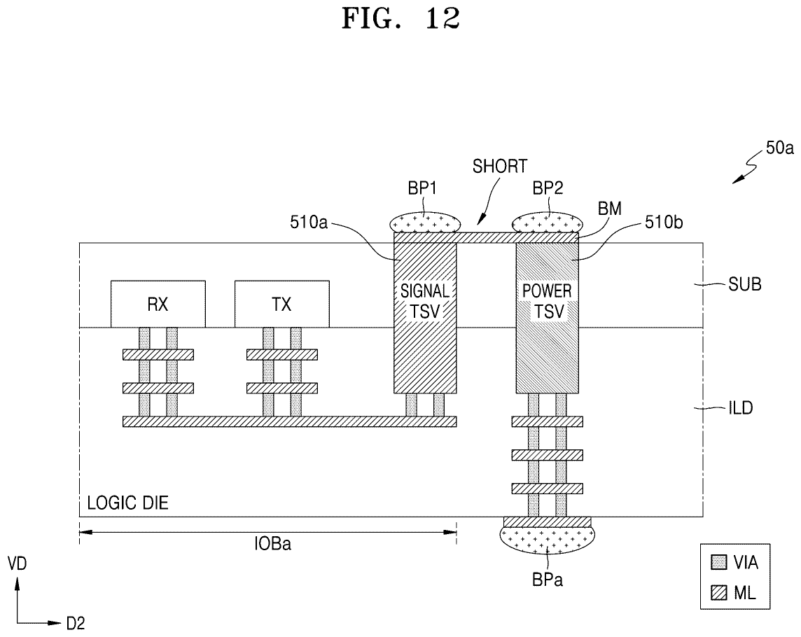

FIG. 12 illustrates an example of a feedback test operation of a logic die 50a, according to at least one embodiment.

Referring to FIG. 12, the logic die 50a may include a signal TSV 510a and a power TSV 510b penetrating a substrate SUB in the vertical direction VD, and the signal TSV 510a and the power TSV 510b may be spaced apart from each other in a horizontal direction (e.g., the second direction D2). A backside metal BM and a first bump BP1 may be arranged on the signal TSV 510a, and the backside metal BM and a second bump BP2 may be arranged on the power TSV 510b. The logic die 50a may be connected to the memory die via the first and second bumps BP1 and BP2. The power voltage received via a bump BPa may be transmitted to the power TSV 510b via a plurality of vias VIA and a plurality of metal layers ML.

The logic die 50a may further include a receiver RX and a transmitter TX arranged on the substrate SUB, and for example, the receiver RX, the transmitter TX, and the signal TSV 510a may be included in a first input/output block (for example, IOBa in FIG. 11). The logic die 50a may further include a plurality of vias VIA and a plurality of metal layers ML, and the plurality of vias VIA and the plurality of metal layers ML, which are adjacent to each other, may be insulated from each other by an insulating layer ILD. The receiver RX may be connected to the signal TSV 510a via the plurality of vias VIA and the plurality of metal layers ML, and may be configured to receive a signal from the signal TSV 510a. The transmitter TX may be connected to the signal TSV 510a via the plurality of vias VIA and the plurality of metal layers ML, and may be configured to transmit a signal to the signal TSV 510a.

For example, a test operation according to the external feedback test mode EFB is described for the case in which the I/F circuit 120 illustrated in FIGS. 5 and 6 includes the receiver RX, the transmitter TX, and the signal TSV 510a. For example, the receiver RX, the transmitter TX, and the signal TSV 510a may correspond to the receiver 123b, the transmitter 123a, and the through silicon via TSV in FIG. 8B, respectively. In the external feedback test mode EFB, the data pattern generator 131 of the test circuit 130 may provide test data ‘0’ to the I/F circuit 120. The test data ‘0’ may be fed back via the write path 121, the transmitter TX 123a, the signal TSV 510a, the receiver RX 123b, the selector 124, and the read path 122, and the feedback data may be provided to the comparator 132 of the test circuit 130.

The power TSV 510b may receive a power voltage, and for example, the power voltage may have a voltage level corresponding to data ‘1’. When a short circuit occurs between the signal TSV 510a and the power TSV 510b, for example, when a short circuit occurs between the backside metal BM connected to the signal TSV 510a and the backside metal BM connected to the power TSV 510b, a signal corresponding to a power voltage level may be transmitted to the signal TSV 510a due to the short with the power TSV 510b. However, the inventive concepts are not limited to thereto, and a short circuit may occur, not only between the backside metals BM, but between various positions (such as bumps, the through silicon vias TSV, the through backside vias TBV, and/or the like). In these cases, the feedback data may include the data ‘1’ corresponding to the power voltage level, and the feedback data ‘1’ may not be the same as the test data ‘0’. Accordingly, it may be determined that a short circuit has occurred at the through silicon via TSV connected to the I/F circuit 120 (e.g., the signal TSV 510a).

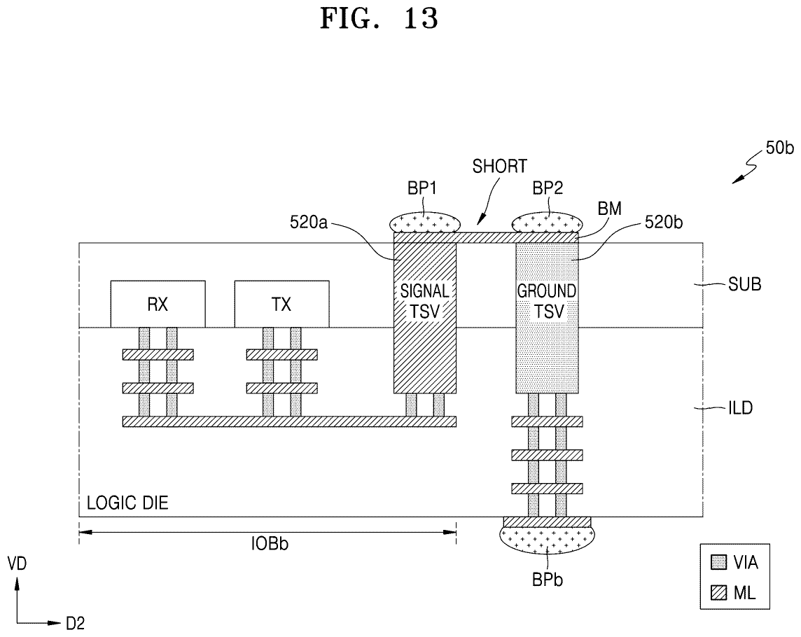

FIG. 13 illustrates an example of the feedback test operation of a logic die 50b, according to at least one embodiment.

Referring to FIG. 13, the logic die 50b may include a signal TSV 520a and a ground TSV 520b, which penetrate the substrate SUB in the vertical direction VD, and the signal TSV 520a and the ground TSV 520b may be spaced apart from each other in a horizontal direction (e.g., the second direction D2). The backside metal BM and the first bump BP1 may be arranged on the signal TSV 520a, and the backside metal BM and the second bump BP2 may be arranged on the ground TSV 520b. The logic die 50b may be connected to the memory die via the first and second bumps BP1 and BP2. The ground voltage received via a bump BPb may be transmitted to the ground TSV 520b via the plurality of vias VIA and the plurality of metal layers ML.

The logic die 50b may further include a receiver RX and a transmitter TX arranged on the substrate SUB, and for example, the receiver RX, the transmitter TX, and the signal TSV 510a may be included in a second input/output block (for example, IOBb in FIG. 11). The logic die 50b may further include a plurality of vias VIA and a plurality of metal layers ML, and the plurality of vias VIA and the plurality of metal layers ML, which are adjacent to each other, may be insulated from each other by an insulating layer ILD. The receiver RX may be connected to the signal TSV 520a via the plurality of vias VIA and the plurality of metal layers ML, and may receive a signal from the signal TSV 520a. The transmitter TX may be connected to the signal TSV 520a via the plurality of vias VIA and the plurality of metal layers ML, and may transmit a signal to the signal TSV 520a.

For example, a test operation according to the external feedback test mode EFB is described for the case in which the I/F circuit 120 illustrated in FIGS. 5 and 6 includes the receiver RX, the transmitter TX, and the signal TSV 520a. For example, the receiver RX, the transmitter TX, and the signal TSV 520a may correspond to the receiver 123b, the transmitter 123a, and the through silicon via TSV in FIG. 8B, respectively. In the external feedback test mode EFB, the data pattern generator 131 of the test circuit 130 may provide the test data ‘1’ to the I/F circuit 120. The test data ‘1’ may be fed back via the write path 121, the transmitter TX 123a, the signal TSV 520a, the receiver RX 123b, the selector 124, and the read path 122, and the feedback data may be provided to the comparator 132 of the test circuit 130.

The ground TSV 520b may receive the ground voltage, and for example, the ground voltage may have a voltage level corresponding to data ‘0’. When a short circuit occurs between the signal TSV 520a and the ground TSV 520b, for example, when a short circuit occurs between the backside metal BM connected to the signal TSV 520a and the backside metal BM connected to the ground TSV 520b, a signal corresponding to a ground voltage level may be transmitted to the signal TSV 520a due to the short with the ground TSV 520b. However, the inventive concepts are not limited to thereto, and a short circuit may occur, not only between the backside metals BM, but between various positions, such as bumps, the through silicon vias TSV, the through backside vias TBV, and/or the like. In these cases, the feedback data may include the data ‘0’ corresponding to the ground voltage level, and the feedback data ‘0’ may not be the same as the test data ‘1’. Accordingly, it may be determined that a short circuit has occurred at the through silicon via TSV connected to the I/F circuit 120 (the signal TSV 520a).

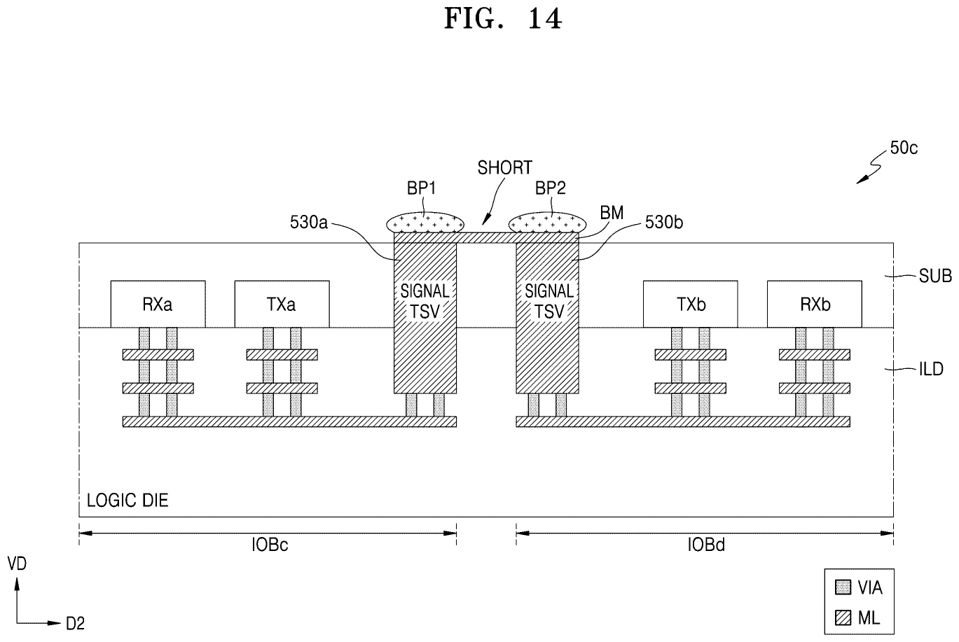

FIG. 14 illustrates an example of a feedback test operation of a logic die 50c, according to at least one embodiment.

Referring to FIG. 14, the logic die 50c may include signal TSVs 530a and 530b penetrating the substrate SUB in the vertical direction VD, and the signal TSVs 530a and 530b may be apart from each other in the second direction D2. The backside metal BM and the first bump BP1 may be arranged on the signal TSV 530a, and the backside metal BM and the second bump BP2 may be arranged on the signal TSV 530b. The logic die 50c may be connected to the memory die via the first and second bumps BP1 and BP2.

The logic die 50c may further include receivers RXl and RXb and transmitters TXa and TXb arranged on the substrate SUB, for example, the receiver RXa, the transmitter TXa, and the signal TSV 530a may be included in a third input/output block (for example, IOBc in FIG. 11), and the receiver RXb, the transmitter TXb, and the signal TSV 530b may be included in a fourth input/output block (for example, IOBd in FIG. 11). The logic die 50c may further include a plurality of vias VIA and a plurality of metal layers ML, and the plurality of vias VIA and the plurality of metal layers ML, which are adjacent to each other, may be insulated from each other by an insulating layer ILD. The receiver RXa may be connected to the signal TSV 530a via the plurality of vias VIA and the plurality of metal layers ML, and may receive a signal from the signal TSV 530a. The transmitter TXa may be connected to the signal TSV 530a via the plurality of vias VIA and the plurality of metal layers ML, and may transmit a signal to the signal TSV 530a. Similarly, the receiver RXb may be connected to the signal TSV 530b via the plurality of vias VIA and the plurality of metal layers ML, and may receive a signal from the signal TSV 530b. The transmitter TXb may be connected to the signal TSV 530b via the plurality of vias VIA and the plurality of metal layers ML, and may transmit a signal to the signal TSV 530b.

For example, during a test operation according to the external feedback test mode EFB, the test circuit 130 may apply the test data ‘1’ to the third input/output block IOBc, and the test data ‘0’ to the fourth input/output block IOBd. In this case, when the feedback data from the third input/output block IOBc is ‘1’, the test circuit 130 may determine that a defect has not occurred in the third input/output block IOBc or a short circuit has not occurred in the signal TSV 530a. On the other hand, when the feedback data from the third input/output block IOBc is ‘0’, the test circuit 130 may determine that a defect has occurred in the third input/output block IOBc or a short circuit has occurred in the signal TSV 530a. Although FIG. 14 illustrates a case in which a short circuit occurs between the backside metals BM, the inventive concepts are not limited thereto, and the short between the signal TSVs 530a and 530b may occur at various positions, such as bumps, the through silicon vias TSV, and the through backside vias TBV.

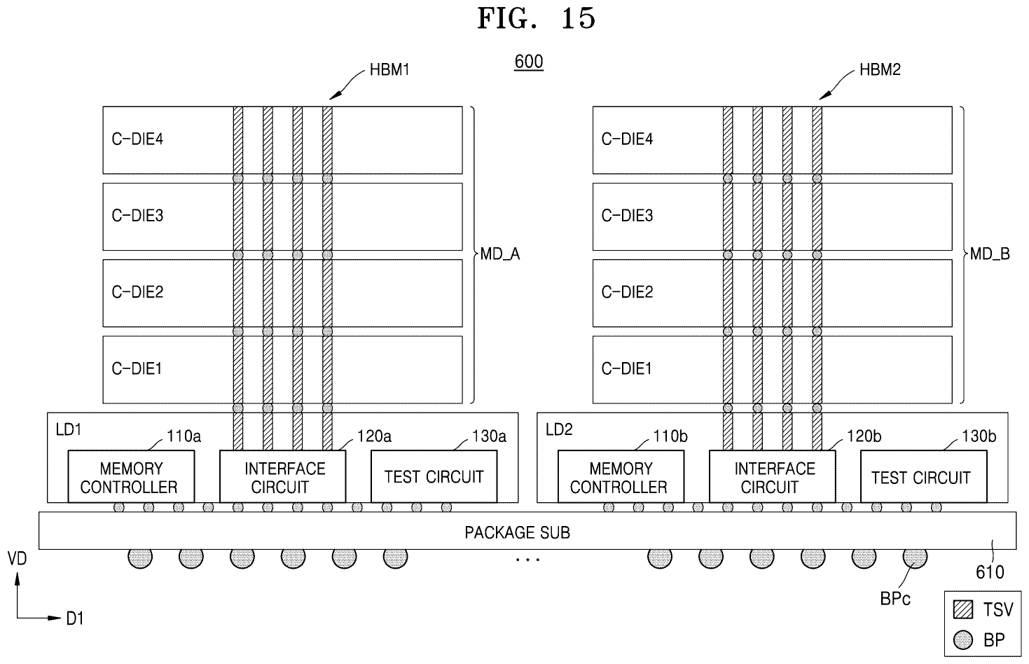

FIG. 15 illustrates an HBM semiconductor device 600 according to at least one embodiment.

Referring to FIG. 15, the HBM semiconductor device 600 may include a first HBM HBM1 and a second HBM HBM2 arranged on the substrate SUB. For example, the first and second HBMs HBM1 and HBM2 may be arranged adjacent to an upper surface of a package substrate 610 in the first direction D1, and the first and second HBMs HBM1 and HBM2 may be electrically connected to the package substrate 610 via the bumps BP. A plurality of connection terminals, for example, bumps BPc, may be arranged under the package substrate 610, and the package substrate 610 may be electrically connected to an external device, for example, a printed circuit board (PCB) via the bumps BPc.

A first HBM HBM1 may include a first logic die LD1 and a plurality of memory dies MD_A stacked on the first logic die LD1 in the vertical direction VD. A second HBM HBM2 may include a second logic die LD2 and a plurality of memory dies MD_B stacked on the second logic die LD2 in the vertical direction VD. For example, each of the plurality of memory dies MD_A and the plurality of memory dies MD_B may include first through fourth core dies C-DIE1 through C-DIE4. The first through fourth core dies C-DIE1 through C-DIE4 may include a plurality of channels having independent interfaces of each other, and accordingly, each of the first and second HBMs HBM1 and HBM2 may have an increased bandwidth.

The first and second HBMs HBM1 and HBM2 may include logic dies according to some embodiments described above with reference to FIGS. 1 through 14. A logic die LD1 of the first HBM HBM1 may include a memory controller 110a, the I/F circuit 120a, and a test circuit 130a. A logic die LD2 of the second HBM HBM2 may include a memory controller 110b, the I/F circuit 120b, and a test circuit 130b. For example, the I/F circuits 120a and 120b may include a plurality of input/output blocks IOB respectively corresponding to a plurality of through silicon vias TSV, and each input/output block IOB may be implemented as illustrated in FIGS. 6, 8A, and 8B.

The first and second HBMs HBM1 and HBM2 may be used for data processing for various purposes, and according to at least one embodiment, the first and second HBMs HBM1 and HBM2 may be used for a neural network computation. As an example, the first and second HBMs HBM1 and HBM2 may perform the neural network computation according to various types of models, such as convolutional neural networks (CNN), recurrent neural networks (RNN), multi-layer perceptron (MLP), deep belief networks, restricted Boltzmann machines, and/or the like.

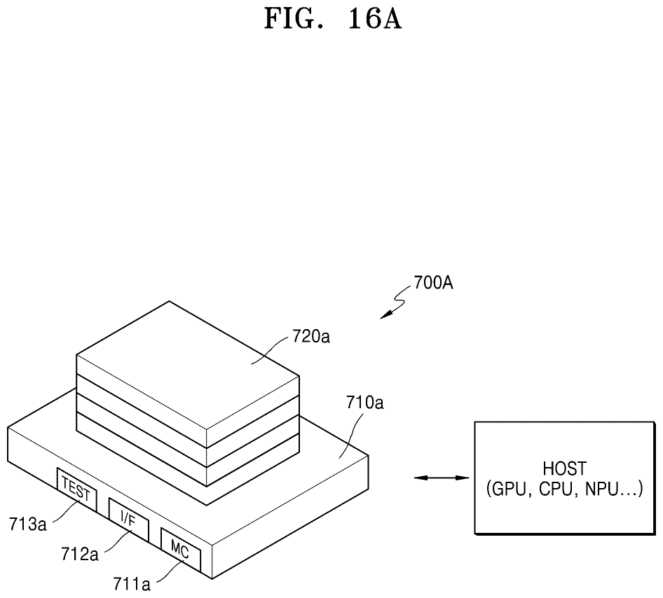

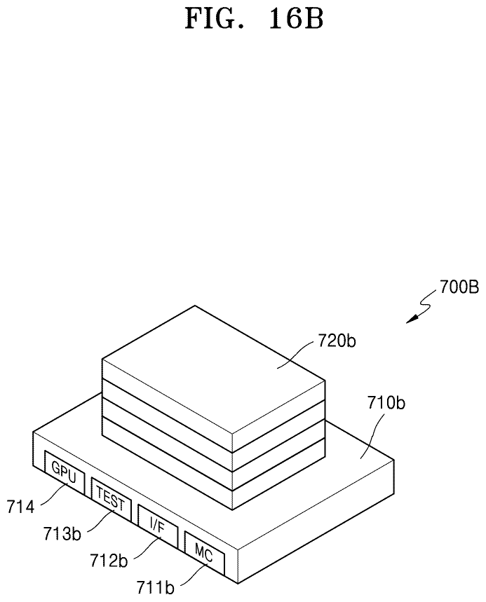

FIGS. 16A and 16B illustrate HBM semiconductor devices 700A and 700B according to some embodiments, respectively.

Referring to FIG. 16A, the HBM semiconductor device 700A may include a logic die 710a and HBM core dies or core dies 720a stacked on the logic die 710a. The logic die 710a may control a memory operation on the core dies 720a in response to a request from an external host. For example, the external host may include a CPU, a GPU, an NPU, an APU, an application processor (AP), and/or the like. The logic die 710a may be electrically connected to the PCB via a plurality of bumps or connection terminals, and the HBM semiconductor device 700A may be implemented as a semiconductor package including the PCB. The logic die 710a may include a memory controller MC 711a, an I/F circuit 712a, and a test circuit 713a, and the logic die 710a may be implemented according to some embodiments illustrated in FIGS. 1 through 14.

Referring to FIG. 16B, the HBM semiconductor device 700B may include a logic die 710b and HBM core dies or core dies 720b stacked on the logic die 710b. The logic die 710b may itself perform a function as a host, and accordingly, may control a memory operation on the core dies 720b. The logic die 710b may include a memory controller MC 711b, an I/F circuit 712b, and a test circuit 713b, and the logic die 710b may be implemented according to some embodiments illustrated in FIGS. 1 through 14. In addition, the logic die 710b may further include various processing devices such as a GPU 714 as the logic die 710b performs the function of the host.

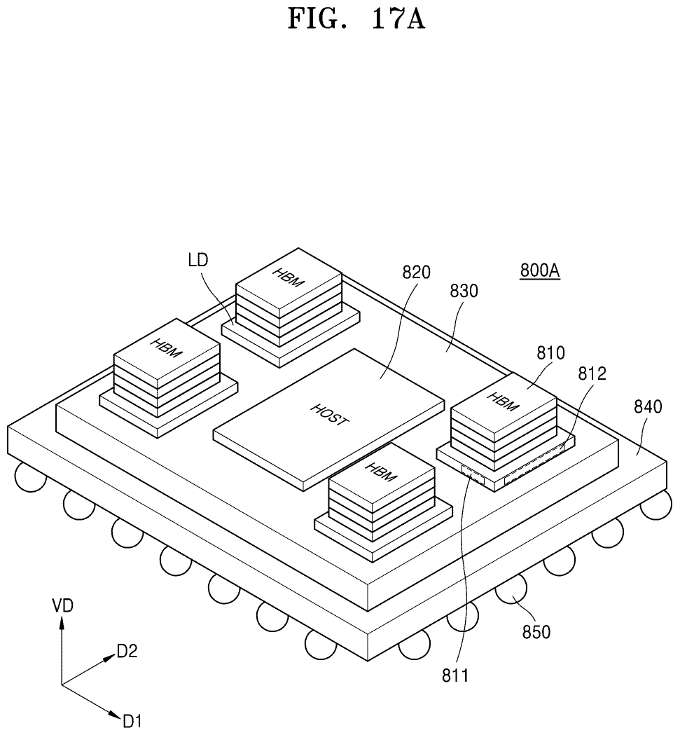

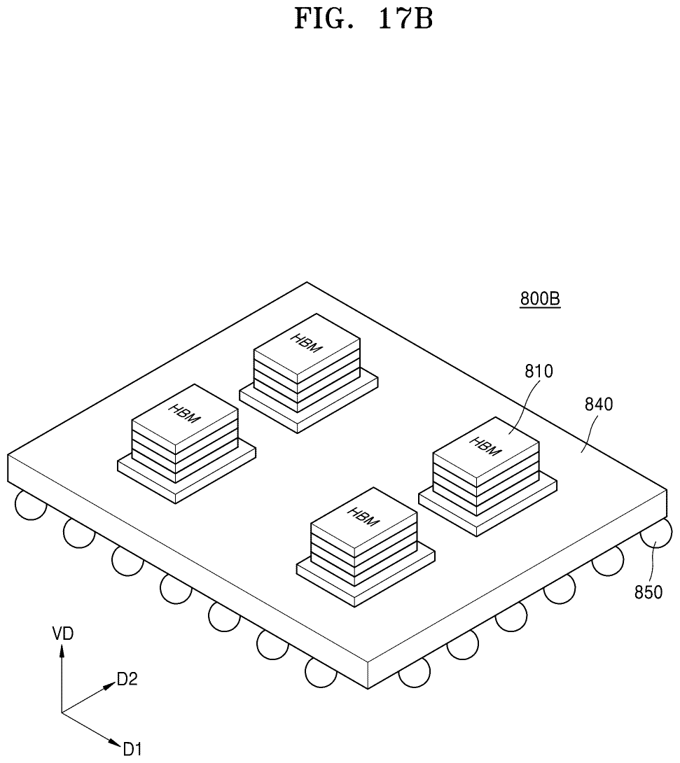

FIGS. 17A and 17B illustrate electronic systems 800A and 800B including semiconductor devices according to some embodiments.

Referring to FIG. 17A, the electronic system 800A may include one or more HBMs 810 and a host 820 according to some embodiments. The HBMs 810 and the host 820 may be mounted on an interposer 830, and the interposer 830, on which the HBMs 810 and the host 820 are mounted, may be mounted on a package substrate 840. The host 820 may correspond to various semiconductor devices requesting memory access.

The HBM 810 may be implemented as a semiconductor device according to the embodiments described above, and accordingly, the HBM 810 may include a logic die LD and a plurality of core dies stacked on the logic die LD. The logic die LD may include an I/F circuit 811 and a memory controller MC 812, and the I/F circuit 811 may include a plurality of input/output blocks IOB or TSV macros, which are respectively connected to the plurality of through silicon vias TSV. The logic die LD may be implemented according to some embodiments illustrated in FIGS. 1 through 14, and accordingly, it may be possible to detect whether defects shorts have occurred in an internal circuit of the logic die LD and/or the through silicon vias TSV, by performing a feedback test operation on the logic die LD before the logic die LD is assembled into the HBM 810.

On the other hand, when the HBM 810 includes a direct access (DA) region, a test signal may be provided into the HBM 810 via conductive means (for example, a solder ball 850) and a DA region, that are mounted under the package substrate 840. The interposer 830 may be implemented in various forms, such as a silicon (TSV) form, a PCB form organic, and an embedded multi-die interconnect bridge (EMIB) of a non-TSV method.

Referring to FIG. 17B, the electronic system 800B may include one or more HBMs 810 according to at least one embodiment. The HBMs 810 may be mounted on the package substrate 840. For example, each HBM 810 may perform itself a function as a host. For example, each HBM 810 may be implemented like the HBM semiconductor device 700B of FIG. 16B. A logic die included in each HBM 810 may be implemented according to some embodiments illustrated in FIGS. 1 through 14, and accordingly, it may be possible to detect whether defects shorts have occurred in an internal circuit of the logic die and/or the through silicon vias TSV, by performing a feedback test operation on the logic die before the logic die is assembled into the HBM 810.

While the inventive concepts have been particularly shown and described with reference to embodiments thereof, it will be understood that various change in form and details may be made therein without departing from the spirit and scope of the following claims.

What is claimed is:

1. A logic die comprising:
a test circuit configured to generate test data for a feedback test operation performed on the logic die;
a plurality of through silicon vias (TSVs) configured to communicate with a memory die; and
an interface circuit connected between the test circuit and the plurality of TSVs, the interface circuit including a write path, a read path, and a TSV input/output circuit connected to a TSV from the plurality of TSVs,
wherein the logic die is configured such that, in a first test mode of the logic die, the test data is fed back to the test circuit via the write path and the read path and not via the TSV input/output circuit, and
wherein the logic die is configured such that, in a second test mode of the logic die, the test data is fed back to the test circuit via the write path, the TSV input/output circuit, the TSV, and the read path.

2. The logic die of claim 1, wherein the interface circuit further comprises:
a selector comprising a first input terminal connected to the write path and a second input terminal connected to the TSV input/output circuit,
wherein, in the first test mode, the logic die is configured such that the test data is fed back to the test circuit via the write path, the selector, and the read path, and
wherein, in the second test mode, the logic die is configured such that the test data is fed back to the test circuit via the write path, the TSV input/output circuit, the TSV, the selector, and the read path.

3. The logic die of claim 2, wherein the selector is configured to:
select one of the first input terminal and the second input terminal based on a control signal; and
provide a signal to the read path, the signal received via the selected one of the first and second input terminals.

4. The logic die of claim 3, wherein, in the first test mode, the logic die is configured such that
the selector selects the first input terminal, and provides a first signal received via the first input terminal to the read path, and
wherein, through the first test mode, the write path, the selector, and the read path are tested.

5. The logic die of claim 3, wherein, in the second test mode, the logic die is configured such that
the selector selects the second input terminal, and provides a second signal received via the second input terminal to the read path, and
wherein, through the second test mode, the TSV input/output circuit and the TSV are tested.

6. The logic die of claim 2, wherein the TSV input/output circuit comprises:
a transmitter electrically connected between the write path and the TSV; and
a receiver electrically connected between the TSV and the selector,
wherein the logic die is configured such that, in the second test mode,
the transmitter and the receiver are enabled, and
the test data is fed back to the second input terminal of the selector via the write path, the transmitter, the TSV, and the receiver.

7. The logic die of claim 6, wherein the logic die is configured such that, in the first test mode,
the transmitter and the receiver are disabled, and
the test data is fed back to the first input terminal of the selector via the write path.

8. The logic die of claim 1, further comprising:
a memory controller configured to control a write operation and a read operation on the memory die.

9. The logic die of claim 8, wherein the logic die is configured such that, in a write mode for the write operation, write data received from the memory controller is transmitted to the memory die via the write path, the TSV input/output circuit, and the TSV, and
wherein the logic die is configured such that, in a read mode for the read operation, read data received from the memory die is transmitted to the memory controller via the TSV, the TSV input/output circuit, and the read path.

10. The logic die of claim 8, further comprising:
a selection circuit including a third input terminal connected to the memory controller and a fourth input terminal connected to the test circuit,
wherein the selection circuit is configured to
in a write mode for the write operation and a read mode for the read operation, select the third input terminal and provide a third signal received to the interface circuit, the third signal received via the third input terminal, and
in the first test mode and the second test mode, select the fourth input terminal and provide a fourth signal received to the interface circuit via the fourth input terminal.

11. The logic die of claim 1, wherein the test circuit comprises:
a data pattern generator configured to generate the test data; and
a comparator configured to compare the test data generated by the test circuit to the data fed back.

12. The logic die of claim 1, wherein the test circuit is configured to:
provide the test data having a ground voltage level to the write path, in order to test whether a short has occurred between the TSV and a power TSV to which a power voltage is applied; and
determine, in the second test mode, that the short has occurred between the TSV and the power TSV when the data fed back to the test circuit does not match the test data generated by the test circuit.

13. The logic die of claim 1, wherein the test circuit is configured to:
provide the test data having a power voltage level to the write path, in order to test whether a short has occurred between the TSV and a ground TSV to which a ground voltage is applied; and
determine, in the second test mode, that the short has occurred between the TSV and the ground TSV when the data fed back to the test circuit does not match the test data generated by the test circuit.

14. The logic die of claim 1, wherein the test circuit is configured to:
provide the test data to the write path to test whether a short circuit has occurred between the TSV and another TSV adjacent thereto; and
determine, in the second test mode, that the short circuit has occurred between the TSV and the another TSV adjacent thereto when the data fed back to the test circuit does not match the test data generated by the test circuit.

15. The logic die of claim 1, further comprising:
at least one of a central processing unit (CPU), a graphics processing unit (GPU), a neural processing unit (NPU), an accelerated processing unit (APU), an application specific integrated circuit (ASIC), or an interface logic configured to communicate with the memory die.

16. A semiconductor device comprising:
a logic die including a memory controller, a test circuit, an interface circuit, and a plurality of through silicon vias (TSVs); and
a plurality of memory dies stacked on the logic die and electrically connected to the logic die via the plurality of TSVs, respectively,
wherein the interface circuit comprises a write path, a read path, and a TSV input/output circuit connected to a TSV from the plurality of TSVs,
wherein the logic die is configured such that, in a first test mode of the logic die, test data is fed back to the test circuit via the write path and the read path and not via the TSV input/output circuit, and
wherein the logic die is configured such that, in a second test mode of the logic die, the test data is fed back to the test circuit via the write path, the TSV input/output circuit, the TSV, and the read path.

17. The semiconductor device of claim 16, wherein the interface circuit further comprises
a selector including a first input terminal connected to the write path and a second input terminal connected to the TSV input/output circuit,
wherein the TSV input/output circuit comprises
a transmitter electrically connected between the write path and the TSV. and
a receiver electrically connected between the TSV and the selector, and
wherein the logic die is configured such that, in the second test mode,
the transmitter and the receiver are enabled, and
the test data is fed back to the second input terminal of the selector via the write path, the transmitter, the TSV, and the receiver.

18. The semiconductor device of claim 17, wherein the logic die is configured such that, in the first test mode,
the transmitter and the receiver are disabled, and
the test data is fed back to the first input terminal of the selector via the write path.

19. The semiconductor device of claim 16, wherein the semiconductor device is implemented as a high bandwidth memory (HBM).

20. A method of feedback testing of a logic die comprising a test circuit, an interface circuit, and a plurality of through silicon vias (TSVs) configured to communicate with a memory die, wherein the interface circuit comprises a TSV input/output circuit connected to one among the plurality of TSVs, a write path, and a read path, the method comprising:
transmitting test data from the test circuit to the write path;
generating, in first test mode of the logic die, first test mode feedback data by giving feedback of the test data to the test circuit via the write path and the read path;
testing, in the first test mode, the write path and the read path by comparing the first test mode feedback data to the test data;
generating, in a second test mode of the logic die, second test mode feedback data by giving feedback of the test data to the test circuit via the write path, the TSV input/output circuit, the TSV, and the read path; and
testing, in the second test mode, the TSV input/output circuit and the TSV by comparing the second test mode feedback data to the test data.
